(19) United States
(12) Patent Application Publication
(10) Pub. No.: US 2001/0045634 A1
(43) Pub. Date: Nov. 29, 2001

(54) Semiconductor package

(76) Inventors: Shi-Baek Nam, Incheon-city (KR); O-Seob Jeon, Seoul (KR)

Correspondence Address: BLAKELY SOKOLOFF TAYLOR & ZAFMAN, 12400 WILSHIRE BOULEVARD, SEVENTH FLOOR, LOS ANGELES, CA, 90025, US

(21) Appl. No.: 09/788,013

(22) Filed: Feb. 16, 2001

(30) Foreign Application Priority Data
Feb. 18, 2000 (KR) 2000-7808

(51) Int. Cl. H01L 23/02

(52) U.S. Cl. 257/678

(57) ABSTRACT

Disclosed is a semiconductor package including: a pad having one power semiconductor device mounted thereon, and a plurality of lead frames including unbent inner frames only, the inner frame being formed on the same line as the pad and electrically connected to the power semiconductor device via a wiring, the lead frames having a first face connected to the wiring, and a second face opposite to the first face. The semiconductor package further includes a molding part formed from an insulating and heat-conductive material and surrounding the power semiconductor device, the pad, and the lead frames. The pad is electrically connected to the power semiconductor device and thereby separated from the lead frames. The lead frames include only inner leads connected to the wiring, and the bottom surface of the lead frames opposite to the top surface connected to the wiring is exposed outwardly together with the bottom surface of the pad, thereby being electrically connected to the printed circuit board via soldering. The lead frames and the pad can be formed, or not, expending out of the boundary of the molding part.

### BACKGROUND OF THE INVENTION

(a) Field of the Invention

The present invention relates to a semiconductor package and, more specifically, to a semiconductor package with a single power semiconductor device and a driver for driving the power device.

(b) Description of the Related Art

In general, a semiconductor package has a power semiconductor device mounted on lead frames by using a conductive adhesive, or a driving device mounted on the lead frames via an insulating adhesive material, the semiconductor package being molded with an epoxy resin together with a heat-resisting metal sheet called “heat sink”.

The lead frames include bottom leads that support the power semiconductor device and the driving device, inner leads that are provided in the body of the semiconductor package via a wiring and upwardly or downwardly bent from the bottom leads, and outer leads that are electrical connections to the exterior and formed extending from the inner leads, thus outwardly protruding from the lateral side of the body of the semiconductor package.

In such a structure that has the lead frames protruding from the body of the semiconductor package, however, the semiconductor package cannot be made thin or small enough even when the chips mounted in the semiconductor package are the same in size, and rather has to be larger in size in order to have higher thermal properties. In this case, the resistance of the package is raised and, especially, the resistance between the source and the drain of the MOS field effect transistor (MOS FET) increases. Due to bent lead frames used, the semiconductor package is made too thick with increased complexity of the fabrication process.

### SUMMARY OF THE INVENTION

It is an object of the present invention to solve the problems and to provide a semiconductor package of which the thickness and size are minimized.

It is another object of the present invention to provide a semiconductor package that can be manufactured by a simple fabrication process.

In one aspect of the present invention, a semiconductor package includes unbent lead frames composed of inner frames only, and a pad for supporting a power semiconductor device, the pad being separated from the lead frames and connected to the power semiconductor device, the bottom surfaces of the pad and the lead frames being outwardly exposed.

More specifically, the semiconductor package according to the present invention includes: a pad having first and second faces opposite to each other, the first face having one power semiconductor device mounted thereon, the pad being formed from a conductive material and electrically connected to the power semiconductor device; a lead frame including only an unbent inner frame, the inner frame being formed on the same line as the pad and connected to the power semiconductor device via a wiring, the lead frame having a first face connected to the wiring, and a second face opposite to the first face; and a molding part formed from an insulating and heat-conductive material and surrounding the power semiconductor device, the pad, and the lead frame, whereby the molding part externally exposes the second faces of the lead frame and the pad.

Preferably, the power semiconductor device includes a discrete device, which has two or three terminals and includes transistor, diode, field effect transistor and thyristor.

The semiconductor package further includes a control circuit mounted on the pad and generating a control signal to drive the power semiconductor device. Preferably, the control circuit is attached to the pad by using an insulating adhesive.

The pad and the lead frame are formed inward the plane boundary of the molding part; the boundary of the pad and the lead frame is positioned on the plane boundary of the molding part; or the pad and the lead frame are formed extending out of the plane boundary of the molding part. The second faces of the pad and the lead frame are formed extending out of the sectional boundary of the molding part, or positioned on the sectional boundary of the molding part.

### BRIEF DESCRIPTION OF THE DRAWINGS

The accompanying drawings, which are incorporated in and constitute a part of the specification, illustrate an embodiment of the invention, and, together with the description, serve to explain the principles of the invention:

FIG. 1 is a schematic view illustrating the structure of a semiconductor package according to a first embodiment of the present invention;

FIG. 2 is a cross-sectional view taken along the line II-II′ of FIG. 1;

FIGS. 3a, 3b and 3c are bottom plan views illustrating the bottom surface of the semiconductor package according to the first embodiment of the present invention;

FIGS. 4a and 4b are schematic cross-sectional views illustrating the structure of the semiconductor package according to the first embodiment of the present invention;

FIG. 5 is a schematic view illustrating the structure of a semiconductor package according to a second embodiment of the present invention;

FIG. 6 is a cross-sectional view taken along the line VI-VI′ of FIG. 5; and

FIG. 7 is a bottom plan view illustrating the bottom surface of the semiconductor package according to the second embodiment of the present invention.

### DETAILED DESCRIPTION OF THE PREFERRED EMBODIMENTS

In the following detailed description, only the preferred embodiment of the invention has been shown and described, simply by way of illustration of the best mode contemplated by the inventor(s) of carrying out the invention. As will be realized, the invention is capable of modification in various obvious respects, all without departing from the invention. Accordingly, the drawings and description are to be regarded as illustrative in nature, and not restrictive.

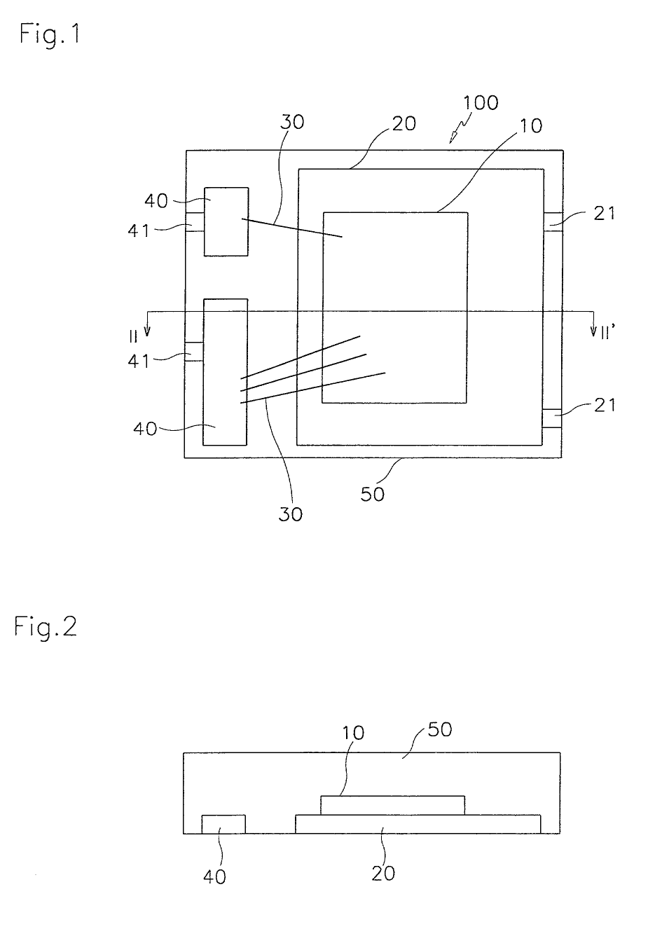

FIG. 1 is a schematic view illustrating the structure of a semiconductor package according to a first embodiment of the present invention, and FIG. 2 is a cross-sectional view taken along the line II-II′ of FIG. 1.

As shown in FIG. 1, the semiconductor package 100 has a power semiconductor device 10 centrally mounted therein, and a pad 20 composed of a material such as copper that has high heat conductivity and low resistance. The semiconductor package 100 also has a plurality of lead frames 40 which are positioned on the same line as the pad 20 and electrically connected to the power semiconductor device 10 via wiring 30. The semiconductor package 100 further includes a molding part 50 composed of a resin such as epoxy molding compound (EMC) and protectively surrounding lead frames 40, wiring 30 and power semiconductor device 10. The molding part 50 is composed of a resin material that has good properties in regard to electrical insulation and heat conductivity. The lead frames 40 and the pad 20 have connections 21 and 41 protruding therefrom, respectively, so that they are fixedly supported by the connections 21 and 41 during the fabrication process of the semiconductor package.

The power semiconductor device 10 according to the embodiment of the present invention is a discrete device having two or three terminals, such as bipolar transistor, MOS field effect transistor (MOS FET), insulated gate bipolar transistor, diode, and thyristor. Two lead frames 40 are, as shown in FIGS. 1 and 2, connected to the two terminals of the power semiconductor device 10. For power semiconductor device 10 with three terminals, the other terminal is connected to the pad 20 so that the pad 20 is isolated from the lead frame 40. The pad 20 is provided not only to externally exhaust heat from the power semiconductor device 10 but also to externally input/output electrical signals.

In such a structure, the lead frames 40 include only inner leads connected to the wiring 30. As shown in the figures, the bottom surface of the semiconductor package, opposing the top surface thereof connected to the wiring 30, as well as the bottom surface of the pad 20 is not surrounded with the molding part 50 but externally exposed, thus being electrically connected to a printed circuit board via soldering. The lead frames 40 are not bent but formed in the same line on a plane. The lead frames 40 and the pad 20 may be formed, or not, extending out of a boundary 52 of the molding part 50, which will be described later in further detail with reference to the accompanying drawings.

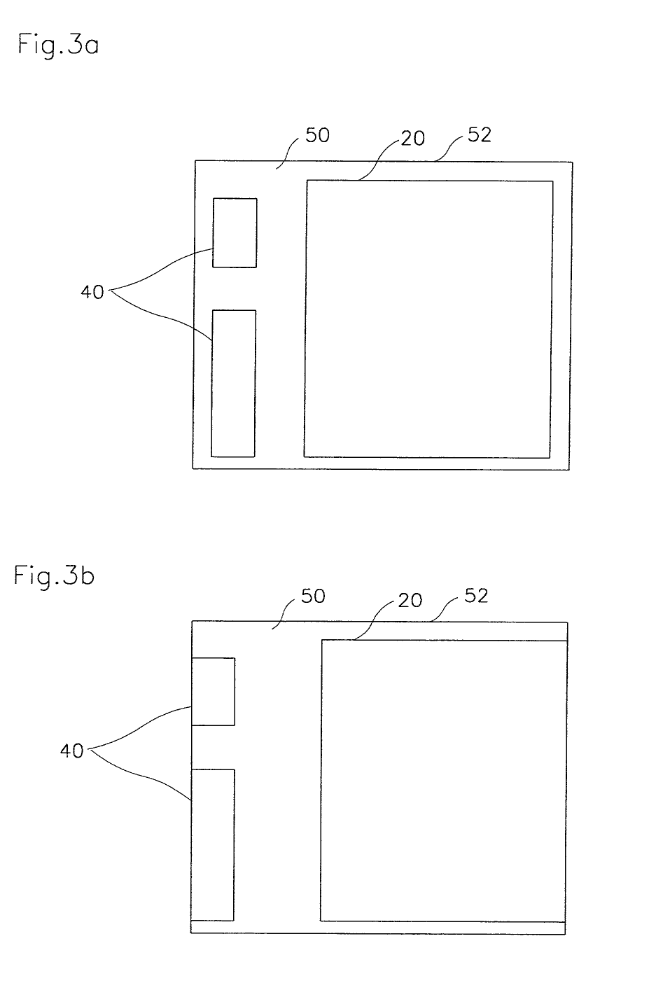

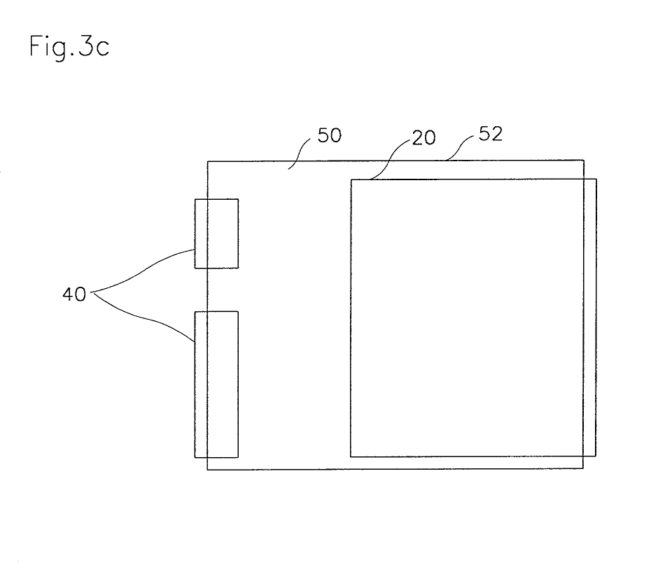

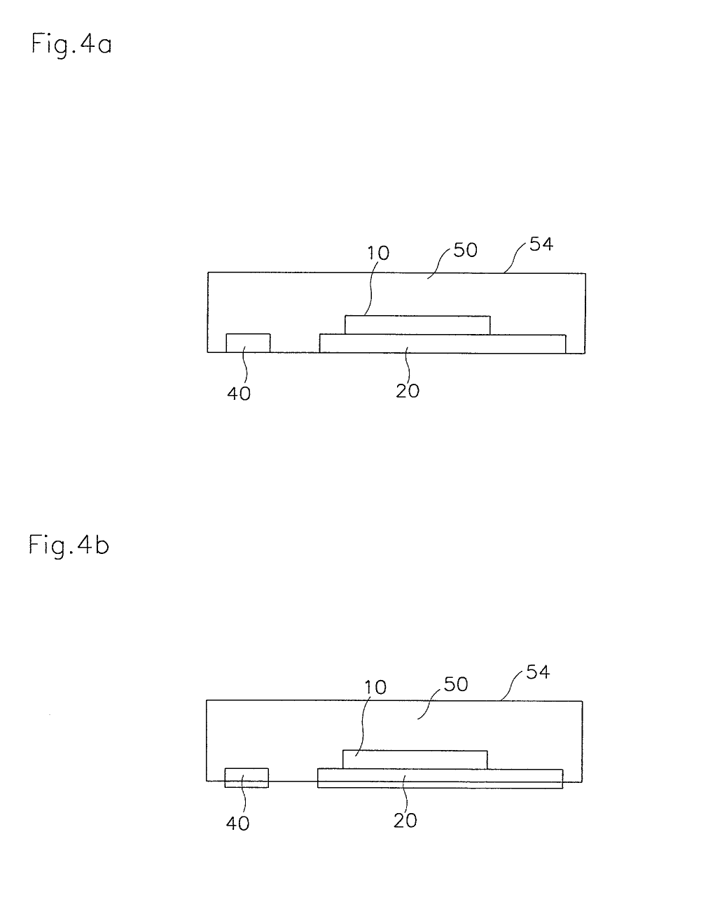

FIGS. 3a, 3b and 3c are bottom plan views illustrating the bottom surface of the semiconductor package according to the embodiment of the present invention, and FIGS. 4a and 4b are schematic cross-sectional views illustrating the structure of the semiconductor package according to the embodiment of the present invention.

First, the semiconductor package according to the embodiment of the present invention may have the lead frames 40 and the pad 20 in three ways: the lead frames 40 and the pad 20 are formed inward the plane boundary 52 of the molding part 50 (in FIG. 3a); part of the boundary of the lead frames 40 and the pad 20 is positioned on the plane board 52 of the molding part 50 (in FIG. 3b); or the lead frames 40 and the pad 20 are formed extending out of the plane boundary 52 of the molding part 50 (in FIG. 3c).

The connections 21 and 42 of FIGS. 1 and 2 are not shown in FIGS. 3a, 3b and 3c, because part of the connections 21 and 41 are etched from the bottom surface of the package 100 or pressed with a mold to have a small thickness and surrounded with the molding part 50.

The bottom surfaces of the lead frames 40 and the pad 20 may be formed is positioned on the bottom of a sectional board 54 of the molding part 50 (in FIG. 4a); or extending in about 0.05 to 0.1 mm out of the bottom of the sectional board 54 of the molding part 50 (in FIG. 4b). This permits soldering more readily performed in mounting the semiconductor package 100 on the printed circuit board.

The embodiment of the present invention reduces the area occupied by the semiconductor package 100 by at least 30% as the lead frames 40 include only inner leads, and the thickness of the semiconductor package 100 by at least 40% due to unbent lead frames 40.

On the other hand, the semiconductor package according to the embodiment of the present invention may include a driver circuit for driving the power semiconductor device, which will be described below with reference to the accompanying drawings.

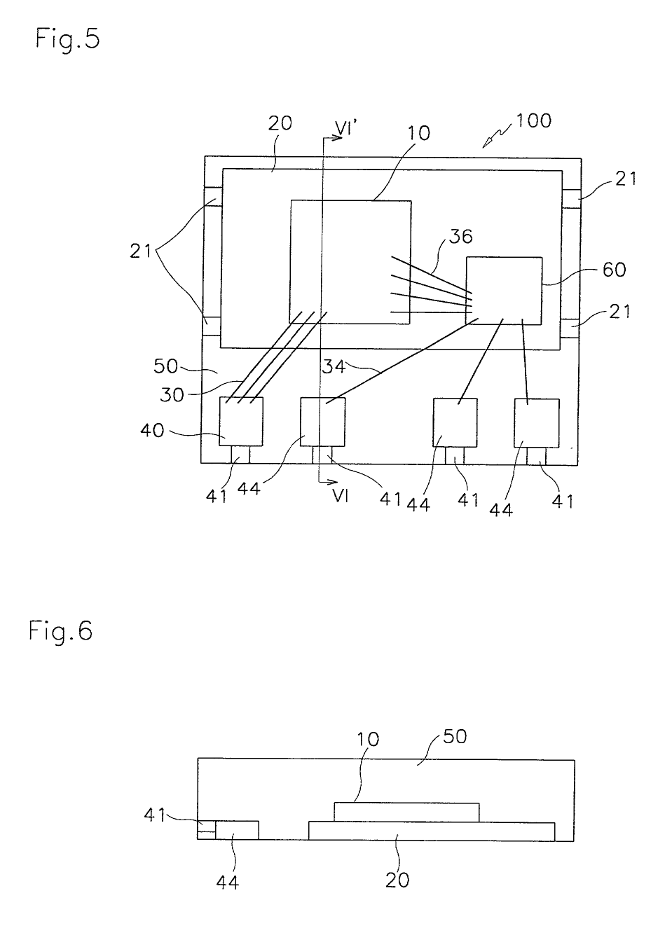

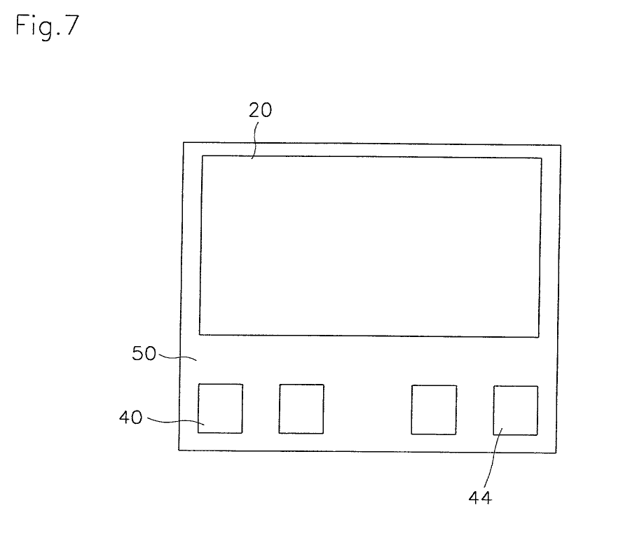

FIG. 5 is a schematic view illustrating the structure of a semiconductor package according to a second embodiment of the present invention, and FIG. 6 is a cross-sectional view taken along the line VI-VI′ of FIG. 5. FIG. 7 is a bottom plan view illustrating the bottom surface of the semiconductor package according to the second embodiment of the present invention.

As is appreciated from FIGS. 5, 6 and 7, the structure of the second embodiment is similar to that of the first embodiment.

The semiconductor package according to the second embodiment of the present invention has a control circuit 60, mounted on the top surface of the pad 20 by using an insulating adhesive, for generating a control signal to drive the power semiconductor device 10. The semiconductor package also has a control lead frame 44 for receiving/generating electrical signals from/to the control circuit 60, and control wirings 36 and 34 for interconnecting the power semiconductor device 10 and the control circuit 60, or electrically connecting the lead frame 44 to the control circuit. The control circuit 60 is attached to the pad 20 by way of an adhesive, which has a good insulating property in consideration of a working voltage between the control circuit 60 and the power semiconductor device 10.

Connections 21 and 41 are surrounded with a molding part 50 and therefore not shown in FIG. 7.

Consequently, the semiconductor package according to the present invention has its thickness and area minimized due to the lead frames formed from inner frames only and reduces the resistance of the lead frames, which accordingly reduces the resistance of the package. The pad with the power semiconductor device thereon can be mounted directly on the printed circuit board to enhance thermal characteristics of the package. Also, the lead frames are so optimized as to minimize the production cost and enhance the production efficiency, and a process for bending lead frames can be omitted to simplify the fabrication process.

While this invention has been described in connection with what is presently considered to be the most practical and preferred embodiment, it is to be understood that the invention is not limited to the disclosed embodiments, but, on the contrary, is intended to cover various modifications and equivalent arrangements included within the spirit and scope of the appended claims.

What is claimed is:

1. A semiconductor package comprising:
a pad having first and second faces opposite to each other, the first face having one power semiconductor device mounted thereon, the pad being formed from a conductive material and electrically connected to the power semiconductor device;
a lead frame including only an unbent inner frame, the inner frame being formed on the same line as the pad and connected to the power semiconductor device via a wiring, the lead frame having a first face connected to the wiring, and a second face opposite to the first face; and
a molding part formed from an insulating and heat-conductive material and surrounding the power semiconductor device, the pad, and the lead frame, whereby the molding part externally exposes the second faces of the lead frame and the pad.

2. The semiconductor package as claimed in claim 1, wherein the power semiconductor device is a discrete device.

3. The semiconductor package as claimed in claim 2, wherein the discrete device has two or three terminals and includes transistor, diode, field effect transistor and thyristor.

4. The semiconductor package as claimed in claim 1, further comprising a control circuit mounted on the pad and generating a control signal to drive the power semiconductor device.

5. The semiconductor package as claimed in claim 4, wherein the control circuit is attached to the pad by using an insulating adhesive.

6. The semiconductor package as claimed in claim 1, wherein the pad and the lead frame are formed inward the plane boundary of the molding part.

7. The semiconductor package as claimed in claim 1, wherein the boundary of the pad and the lead frame is positioned on the plane boundary of the molding part.

8. The semiconductor package as claimed in claim 1, wherein the pad and the lead frame are formed extending out of the plane boundary of the molding part.

9. The semiconductor package as claimed in claim 1, wherein the second faces of the pad and the lead frame are formed extending out of the sectional boundary of the molding part.

10. The semiconductor package as claimed in claim 1, wherein the pad and the lead frame are positioned on the sectional boundary of the molding part.
